(19) United States
(12) Patent Application Publication
(10) Pub. No.: US 2003/0080357 A1
(43) Pub. Date: May 1, 2003

(54) Integrated circuit with internal signals immune from noises and manufacturing method thereof

(76) Inventors: Hung-Yin Tsai, Taipei (TW); Ching-Fu Chuang, Taichung (TW); Heng-Chen Ho, Dali City (TW)

Correspondence Address: OPPENHEIMER WOLFF & DONNELLY, P. O. BOX 10356, PALO ALTO, CA, 94303, US

(21) Appl. No.: 10/057,055

(22) Filed: Jan. 25, 2002

(30) Foreign Application Priority Data
Oct. 25, 2001 (TW) 90126366

(51) Int. Cl. H01L 27/10

(52) U.S. Cl. 257/203

(57) ABSTRACT

The present invention provides an integrated circuit with high-frequency signals immune from noises. The integrated circuit has a chip having a first pad and a plurality of second pads, wherein an AC signal and DC signals are transmitted through the first pad and the second pads respectively, a substrate having a first finger and a plurality of second fingers, a first conducting line connected between the first pad and finger respectively of the chip and substrate, and a plurality of second conducting lines connected between the second pads and fingers respectively of the chip and substrate, and surrounding the first conducting line.

### BACKGROUND OF THE INVENTION

1. Field of the Invention

The present invention relates to an integrated circuit and a manufacturing method thereof, particularly to an integrated circuit with internal signals immune from noises and a manufacturing method thereof.

2. Description of the Prior Art

In an integrated circuit manufacturing process, gold lines are bonded to pads on a chip and fingers on a substrate before molding. Thus, the solder balls or pins of the substrate for connection and signal transmission with external circuits are electrically connected to the pads of the chip.

FIG. 1A is a diagram showing an integrated circuit with bonded gold lines arranged conventionally. The integrated circuit comprises a substrate 11, a chip 12 and gold lines 13₁˜13₁₂. The chip 12 has 12 pads 121 through which 3 ground signals GND1˜GND3, 6 data signals D1˜D6, one clock signal CLK and 2 strobe signals S1˜S2 are transmitted. The pads 121 are electrically connected to fingers 111 on the substrate 11. The substrate 11 further comprises a ground ring 112 and power ring 113.

FIG. 1B is a diagram showing a cross-section of the gold lines 13₁˜13₁₂ along a line AA′ in FIG. 1A. The strobe signals S1 and S2 are transmitted through the gold lines 13₁ and 13₄, the clock signal CLK is transmitted through the gold line 13₂, the ground signals GND1˜GND3 are transmitted through the gold lines 13₃, 13₉ and 13₁₂, and the data signals D1˜D6 are transmitted through the gold lines 13₅˜13₈, 13₁₀ and 13₁₁.

However, noises are easily generated in the gold lines carrying AC signals such as the clock, strobe and data signals since they interfere with each other, especially for signals with high frequency. The conventional arrangement does not make a proper separation of the gold lines carrying the AC signals from each other. Additionally, the fingers on the substrate are arranged in one single row, which results in small pitches between the gold lines. This increases the probability of improper contact of two adjacent gold lines when molding.

### SUMMARY OF THE INVENTION

Therefore, the object of the present invention is to provide an integrated circuit and a manufacturing method thereof wherein gold lines carrying AC signals are separated, each of them is surrounded by gold lines carrying DC signals and the probability of improper contact of gold lines is decreased by large pitches between the lines.

The present invention provides an integrated circuit with high-frequency signals immune from noises. The integrated circuit has a chip having a first pad and a plurality of second pads, wherein an AC signal and DC signals are transmitted through the first pad and the second pads respectively, a substrate having a first finger and a plurality of second fingers, a first conducting line connected between the first pad and finger respectively of the chip and substrate, and a plurality of second conducting lines connected between the second pads and fingers respectively of the chip and substrate, and surrounding the first conducting line.

The present invention further provides a method for manufacturing an integrated circuit comprising the steps of providing a substrate and a chip having a first pad and a plurality of second pads, wherein an AC signal and DC signals are transmitted through the first pad and the second pads respectively, forming a first and a plurality of second fingers on the substrate, bonding a first conducting line to the first pad and finger, and bonding to the second pads and fingers a plurality of second conducting lines surrounding the first conducting line.

### BRIEF DESCRIPTION OF THE DRAWINGS

The following detailed description, given by way of example and not intended to limit the invention solely to the embodiments described herein, will best be understood in conjunction with the accompanying drawings, in which:

FIG. 1A is a diagram showing an integrated circuit with bonded gold lines arranged conventionally.

FIG. 1B is a diagram showing a cross-section of the gold lines 13₁˜13₁₂ along a line AA′ in FIG. 1A.

FIG. 2A is a diagram showing an integrated circuit with bonded gold lines according to a first embodiment of the invention.

FIG. 2B is a diagram showing a cross-section of the gold lines 23₁˜23₁₂ along a line AA′ in FIG. 2A.

FIG. 3A is a diagram showing an integrated circuit with bonded gold lines according to a second embodiment of the invention.

FIG. 3B is a diagram showing a cross-section of the gold lines 33₁˜33₁₂ along a line AA′ in FIG. 3A.

FIG. 4 is a flow chart showing a method for manufacturing an integrated circuit according to one embodiment of the invention.

### DETAILED DESCRIPTION OF THE INVENTION

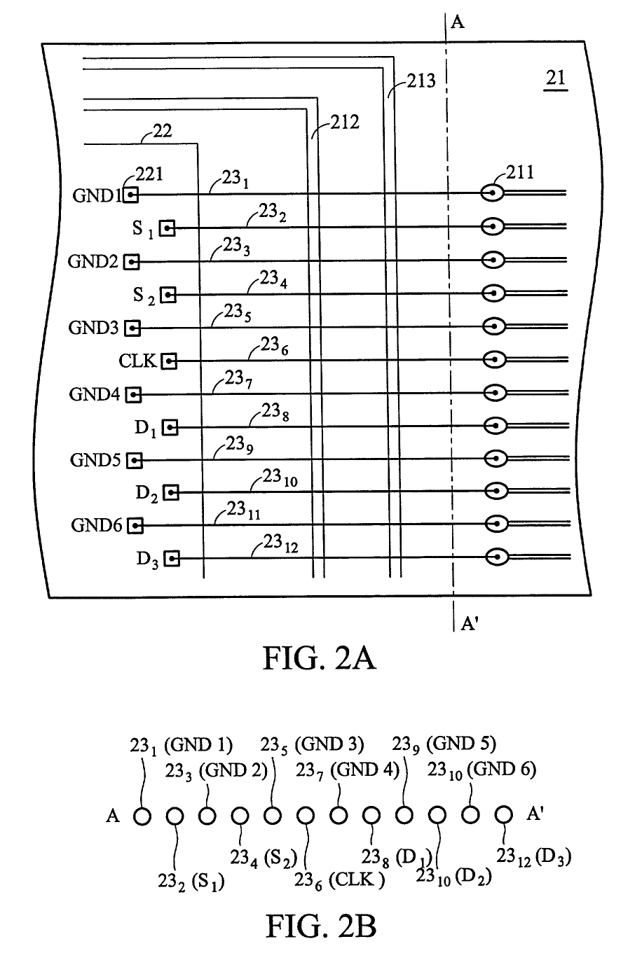

FIG. 2A is a diagram showing an integrated circuit with bonded gold lines according to a first embodiment of the invention. The integrated circuit comprises a substrate 21, a chip 22 and gold lines 23₁˜23₁₂. The chip 22 has 12 pads 221 through which 6 ground signals GND1˜GND6, 3 data signals D1˜D3, one clock signal CLK and 2 strobe signals S1˜S2 are transmitted. The pads 221 are electrically connected to fingers 211 arranged in a row on the substrate 21. The substrate 21 further comprises a ground ring 212 and power ring 213.

FIG. 2B is a diagram showing a cross-section of the gold lines 23₁˜23₁₂ along a line AA′ in FIG. 2A. The strobe signals S1 and S2 are transmitted through the gold lines 23₂ and 23₄, the clock signal CLK is transmitted through the gold line 23₆, the ground signals GND1˜GND6 are transmitted through the gold lines 23₁, 23₃, 23₅, 23₇, 23₉ and 23₁₁, and the data signals D1˜D3 are transmitted through the gold lines 23₈, 23₁₀ and 23₁₂.

Consequently, in the first embodiment, all the gold lines 23₂, 23₄, 23₆, 23₈, 23₁₀ and 23₁₂ carrying AC signals are separated from each other by the gold lines 23₁, 23₃, 23₅, 23₇, 23₉ and 23₁₁ carrying DC signals (the ground signal). Each of the gold lines carrying the DC signals is placed between two of the gold lines carrying the AC signals, that is to say, each of the gold lines carrying the AC signals is surrounded by two of the gold lines carrying the DC signals. Thus, the interference between the AC signals and the noises resulting therefrom is prevented.

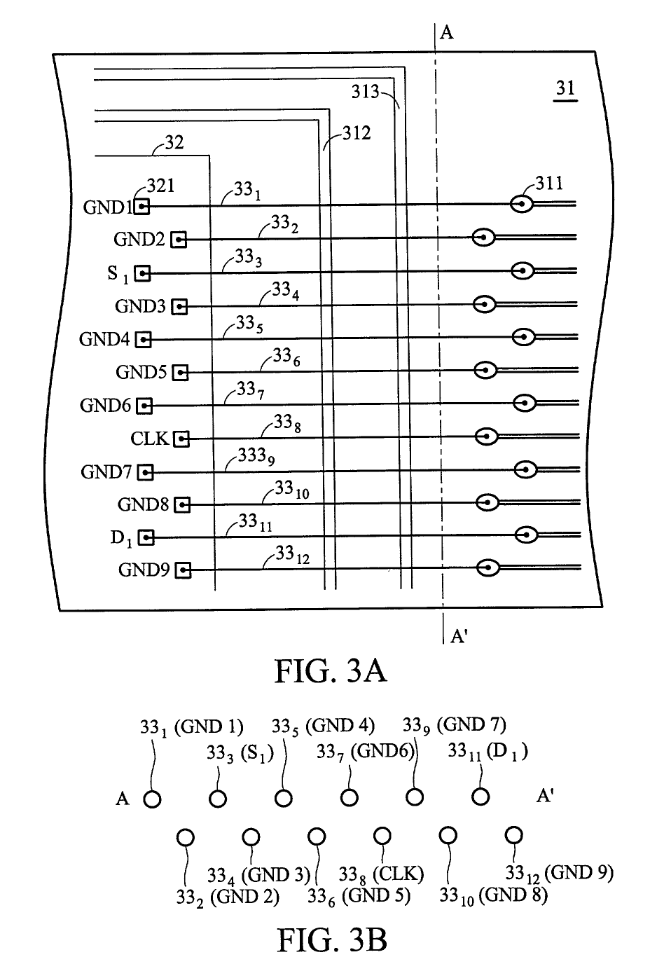

FIG. 3A is a diagram showing an integrated circuit with bonded gold lines according to a second embodiment of the invention. The integrated circuit comprises a substrate 31, a chip 32 and gold lines 33₁˜33₁₂. The chip 32 has 12 pads 321 through which 9 ground signals GND1˜GND9, 1 data signals D1, one clock signal CLK and one strobe signal S1 are transmitted. The pads 321 are electrically connected to fingers 311 arranged in two rows on the substrate 31. The substrate 31 further comprises a ground ring 312 and power ring 313.

FIG. 3B is a diagram showing a cross-section of the gold lines 33₁˜33₁₂ along a line AA′ in FIG. 3A. The fingers 311 are arranged in two rows, whereby the lengths and curvatures of the gold lines 33₁˜33₁₂ are different. Therefore, the cross-section of the gold lines comprises two levels. Those bonded to the fingers arranged in the right and left row on the substrate 31 in FIG. 3A are respectively in the top and bottom level. The strobe signals S1 are transmitted through the gold lines 33₃, the clock signal CLK is transmitted through the gold line 33₈, the ground signals GND₁˜GND₉ are transmitted through the gold lines 33₁, 33₂, 33₄, 33₅, 33₆, 33₇, 33₉, 33₁₀ and 33₁₂, and the data signals D1 is transmitted through the gold lines 33₁₁.

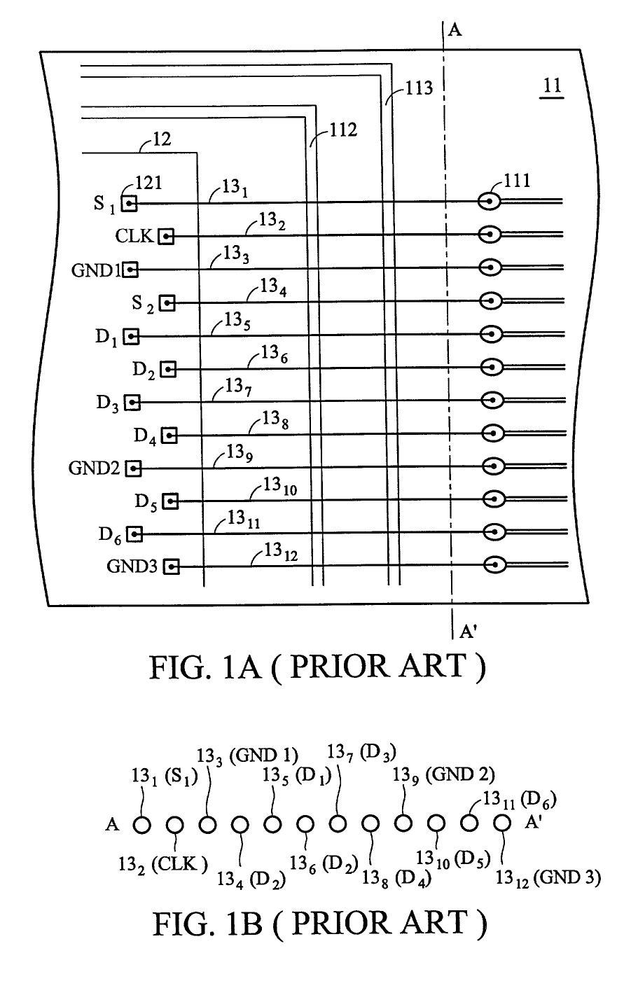

Consequently, in the second embodiment, all the gold lines 33₃, 33₈, and 33₁₁ carrying AC signals are separated from each other by the gold lines 33₁, 33₂, 33₄, 33₅, 33₆, 33₈, 33₉, 33₁₀ and 33₁₂ carrying DC signals (the ground signal). Each of the gold lines carrying the AC signals is surrounded by four of the gold lines carrying the DC signals. Thus, the interference between the AC signals and the noises resulting therefrom is prevented. Further, the pitches between the gold lines are twice as large as those in FIGS. 1B and 2B since the gold lines are placed in two levels with different heights, which decreases the probability of improper contact of the gold lines when molding.

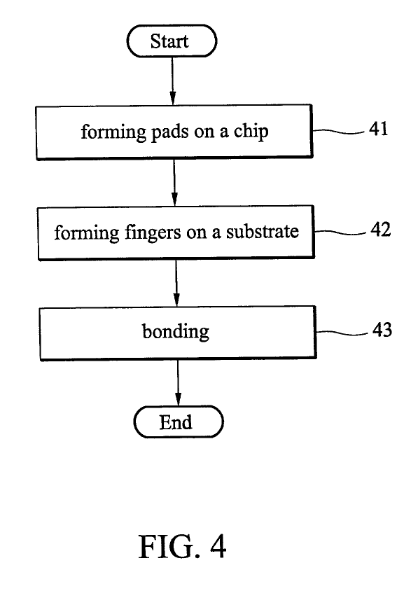

FIG. 4 is a flow chart showing a method for manufacturing an integrated circuit according to one embodiment of the invention.

In step 41, pads are formed on a chip, wherein the pads for AC signal (data, clock or strobe signals for example) transmitting are surrounded by those for DC signal (ground signal for example) transmitting.

In step 42, fingers are formed on a substrate and arranged in two rows. In the row closer to the chip, all the fingers are for electrical connection to the pads for DC signal transmission. In the other row, the fingers for electrical connection to the pads for DC and AC signal transmission are alternatively arranged.

In step 43, gold lines are bonded to the pads and fingers for the electrical connections described above. Each of the gold lines carrying the AC signals is surrounded by four gold lines carrying the DC signals since the height of those bonded to the fingers in the row closer to the chip is shorter than the height of those bonded to the fingers in the other row in which the fingers for AC and DC signal transmission are alternatively arranged.

In the second embodiment, the fingers can be arranged in more than two rows so that each of the gold lines for AC signals is surrounded by more than four DC signal gold lines.

In conclusion, in the invention, the pads and fingers are specially arranged and the number of the pads for DC signal transmission is increased, whereby each of the gold lines for AC signal transmission is surrounded by more than two of those for DC signal transmission and the pitches between them are also enlarged. Thus, the interference between the AC signals and the noises resulting therefrom is prevented and the probability of improper contact of the gold lines is also decreased.

While the invention has been described by way of example and in terms of the preferred embodiment, it is to be understood that the invention is not limited to the disclosed embodiments. On the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. An integrated circuit with internal signals immune from noises comprising:
a chip having a first pad and a plurality of second pads, wherein an AC signal and DC signals are transmitted through the first pad and the second pads respectively;
a substrate having a first finger and a plurality of second fingers;
a first conducting line connected between the first pad and finger respectively of the chip and substrate; and
a plurality of second conducting lines connected between the second pads and fingers respectively of the chip and substrate, and surrounding the first conducting line.

2. The integrated circuit as claimed in claim 1 wherein the AC signal is a clock signal.

3. The integrated circuit as claimed in claim 1 wherein the AC signal is a strobe signal.

4. The integrated circuit as claimed in claim 1 wherein the AC signal is a data signal.

5. The integrated circuit as claimed in claim 1 wherein the DC signal is a ground signal.

6. The integrated circuit as claimed in claim 1 wherein the first and second fingers are arranged in a row and the first finger is placed between the second fingers.

7. The integrated circuit as claimed in claim 1 wherein the first and second fingers are arranged in a plurality of rows.

8. The integrated circuit as claimed in claim 1 wherein one of the first and second conducting lines is made of gold.

9. A method for manufacturing an integrated circuit comprising the steps of:
providing a substrate and a chip having a first pad and a plurality of second pads, wherein an AC signal and DC signals are transmitted through the first pad and the second pads respectively;
forming a first and a plurality of second fingers on the substrate;
bonding a first conducting line to the first pad and finger; and
bonding to the second pads and fingers a plurality of second conducting lines surrounding the first conducting line.

10. The method as claimed in claim 9 wherein the AC signal is a clock signal.

11. The method as claimed in claim 9 wherein the AC signal is a strobe signal.

12. The method as claimed in claim 9 wherein the AC signal is a data signal.

13. The method as claimed in claim 9 wherein the DC signal is a ground signal.

14. The method as claimed in claim 9 wherein the first and second fingers are arranged in a row and the first finger is placed between the second fingers.

15. The method as claimed in claim 9 wherein the first and second fingers are arranged in a plurality of rows.

16. The method as claimed in claim 9 wherein one of the first and second conducting lines is made of gold.
